(19) United States
(12) Patent Application Publication
(10) Pub. No.: US 2026/0101523 A1
(43) Pub. Date: Apr. 9, 2026

(54) METAL-INSULATOR-METAL CAPACITOR WITH PROTECTION LAYER

(71) Applicant: International Business Machines Corporation, Armonk, NY (US)

(72) Inventors: Qianwen Chen, Fort Collins, CO (US); Joshua Mark Rubin, Albany, NY (US); Tao Li, Slingerlands, NY (US); Emmanuel Abreu, Sewaren, NJ (US); Ruilong Xie, Niskayuna, NY (US)

(21) Appl. No.: 18/909,463

(22) Filed: Oct. 8, 2024

(51) Int. Cl. H01L 23/48

(52) U.S. Cl. CPC H10D 1/043; H10D 1/714; H10W 20/20

(57) ABSTRACT

A capacitor structure includes at least one metal-insulator-metal capacitor device and at least one protection layer vertically overlapped with at least a portion of the at least one metal-insulator-metal capacitor device. The capacitor structure also includes a first metallization layer and a second metallization layer, where the at least one metal-insulator-metal capacitor device is positioned between the first and the second metallization layers.

### BACKGROUND

Capacitors are passive circuit components that are utilized in integrated circuits for various purposes. For example, capacitors can be utilized to decouple power supplies, to form memory elements, to form resistor-capacitor (RC) delay circuits, or provide various other circuit functions. While many types of capacitor structures can be utilized, metal-insulator-metal (MIM) capacitors are frequently used for analog, microwave, and radio frequency (RF) applications. MIM capacitors typically include two or more electrodes separated by an insulator layer.

### SUMMARY

Embodiments described herein provide structures and techniques for forming MIM capacitors with one or more protection layers.

In one embodiment, a capacitor structure includes at least one metal-insulator-metal capacitor device and at least one protection layer vertically overlapped with at least a portion of the at least one metal-insulator-metal capacitor device. The capacitor structure includes a first metallization layer and a second metallization layer, where the at least one metal-insulator-metal capacitor device is positioned between the first and the second metallization layers.

In another embodiment, a capacitor structure includes a metal-insulator-metal capacitor device and at least one protection layer vertically overlapped with at least a portion of the metal-insulator-metal capacitor device. The capacitor structure also includes at least one metallization layer. A combined area of the at least one protection layer and the at least one metallization layer covers an entire area of a first surface of the metal-insulator-metal capacitor device.

In another embodiment, a method includes depositing a first protection layer above a first metallization layer of a capacitor structure and forming a metal-insulator-metal capacitor device above the first protection layer. The method also includes depositing a second protection layer above the metal-insulator-metal capacitor device, and forming at least two vias, where a first one of the at least two vias electrically connects the first metallization layer to a first electrode of the metal-insulator-metal capacitor device, and a second one of the at least two vias electrically connects a second metallization layer of the capacitor structure to a second electrode of the metal-insulator-metal capacitor device.

These and other features and advantages of embodiments described herein will become more apparent from the accompanying drawings and the following detailed description.

### BRIEF DESCRIPTION OF THE DRAWINGS

FIG. 1 is a schematic cross-sectional view of a capacitor structure at an intermediate stage of fabrication, according to an embodiment.

FIG. 2 is a schematic cross-sectional view of the capacitor structure following deposition of an interlayer dielectric (ILD) layer, according to an embodiment.

FIG. 3 is a schematic cross-sectional view of the capacitor structure following formation of a MIM capacitor device, according to an embodiment.

FIG. 4 is a schematic cross-sectional view of the capacitor structure following deposition of dielectric material, according to an embodiment.

FIG. 5 is a schematic cross-sectional view of the capacitor structure following formation of a protection layer, according to an embodiment.

FIG. 6 is a schematic cross-sectional view of the capacitor structure following deposition of additional dielectric material, according to an embodiment.

FIG. 7 is a schematic cross-sectional view of the capacitor structure following via formation, according to an embodiment.

FIG. 8 is a schematic cross-sectional view of the capacitor structure following formation of another interlayer dielectric (ILD) layer and conductive lines, according to an embodiment.

FIG. 9 is a schematic cross-sectional view of an alternate capacitor structure, according to an embodiment

### DETAILED DESCRIPTION

Illustrative embodiments are described herein in the context of illustrative methods for forming MIM capacitors with one or more protection layers, along with illustrative apparatus, systems and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Laser technologies are widely used in semiconductors for heterogeneous integration (HI) and Chiplet applications. For example, laser-assisted bonding benefits from the fact that laser energy leads to a small, localized impact of heat to process individual components. Fast heating rates under pyrometer control prevent oxidation of surfaces and lead to short production cycles for the individual components. However, when the thickness of the die is thinned down to approximately 100 um, a significant amount of the laser energy can transmit through the silicon substrate and negatively affect the device (e.g., capacitor).

This issue is particularly problematic for MIM capacitor devices as metal plates corresponding to electrodes are often thin and have a high absorptance rate of laser energy. The laser energy can penetrate the silicon substrate of a MIM capacitor device, potentially from the top and/or bottom during various processing steps, which can potentially lead to physical damage of the electrodes of the MIM capacitor. Accordingly, there is a need for a capacitor structure that can safeguard the electrodes of a MIM capacitor device without compromising the benefits of advanced laser-assisted processes such as rapid localized heating and reduced oxidation.

As discussed in further detail below, MIM capacitor structures are fabricated with one or more protection layers to help protect the electrodes from damage, for example, by laser energy.

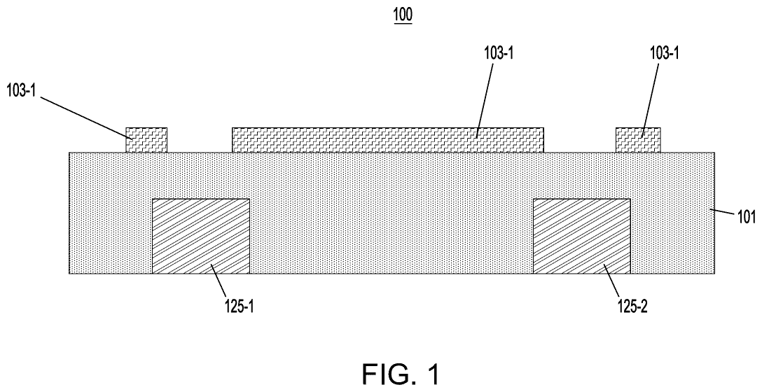

FIGS. 1-9 schematically illustrate techniques for fabricating a MIM capacitor structure having a protection layer. FIG. 1 is a schematic cross-sectional view of a capacitor structure 100 at an intermediate stage of fabrication. The capacitor structure 100 comprises a first ILD layer 101, conductive (e.g., metal) lines 125-1 and 125-2 (collectively “conductive lines 125”) formed in the first ILD layer 101, and a first protection layer 103-1 formed on the first ILD layer 101. In some embodiments, the conductive lines 125 correspond to power distribution lines.

The first ILD layer 101 is formed of any suitable dielectric material that is commonly utilized in back-end-of-line (BEOL) fabrication technologies. For example, the first ILD layer 101 can be formed of a dielectric material including, but not limited to, silicon oxide (SiO2), silicon nitride (e.g., Si3N4), hydrogenated silicon carbon oxide (SiCOH), hydrogenated silicon carbide (SiCH), SiCNH, tetraethyl orthosilicate (TEOS), or other types of silicon-based low-k dielectrics (e.g., k less than about 4.0), porous dielectrics, or known ULK (ultra-low-k) dielectric materials (with k less than about 2.5). The first ILD layer 101 is deposited using known deposition techniques, such as atomic layer deposition (ALD), chemical vapor deposition (CVD), plasma-enhanced CVD (PECVD), physical vapor deposition(PVD), or spin-on deposition.

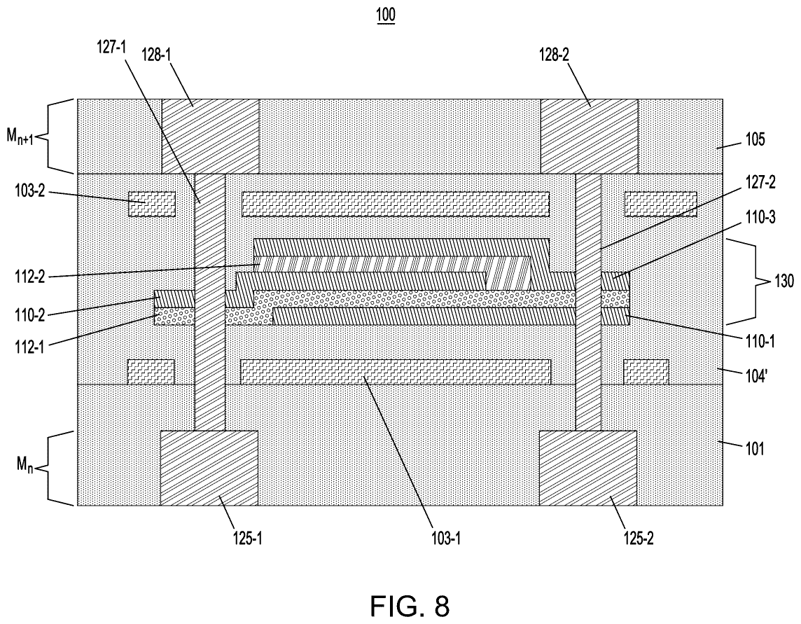

The conductive lines 125 comprise a plurality of parallel metal lines which, according to illustrative embodiments, include a positive power supply voltage line (e.g., VDD metal line) and a negative power supply voltage line (e.g., GND metal line). The conductive lines 125 are formed by a process that comprises patterning trenches in the first ILD layer 101, lining the trenches with a liner layer (e.g., diffusion barrier and/or seed layer), and filling the trenches with metallic material such as copper or other suitable metallic materials. In one embodiment, the conductive lines 125 are formed as part of a lower metallization layer (e.g., Mₙ (see FIG. 8)).

The first protection layer 103-1 is formed on the first ILD layer 101 by a process that includes deposition of a reflective material comprising one or more reflective metals (e.g., aluminum, platinum, chromium, or tungsten). The reflective material is then patterned with, for example, lithography and etching (e.g., using reactive ion etching, wet etching, ion beam etching, etc.) to form the first protection layer 103-1 as shown in FIG. 1. In some embodiments, the first protection layer 103-1 is formed with a thickness suitable for blocking incoming infrared (IR) laser irradiation energy. In one embodiment, the thickness of the first protection layer 103-1 can be approximately 100 nm or greater. In other embodiments, the first protection layer 103-1 can be formed with any other suitable process (e.g., a damascene process).

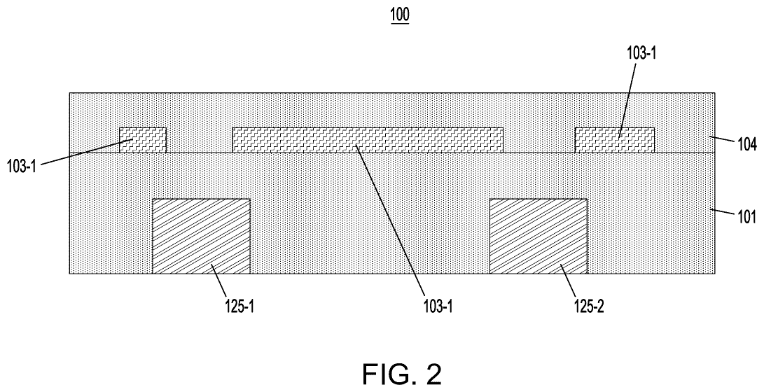

FIG. 2 is a schematic cross-sectional view of the capacitor structure following deposition of a second ILD layer 104, according to an embodiment. The second ILD layer 104 is formed so that it covers the first protection layer 103-1. The second ILD layer 104 is formed using the same or similar techniques and materials as the first ILD layer 101.

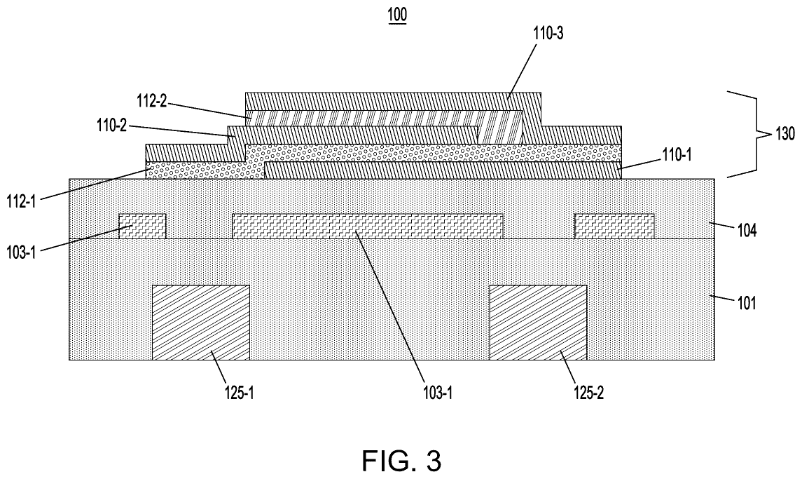

FIG. 3 is a schematic cross-sectional view of the capacitor structure 100 following formation of a MIM capacitor device 130. A first conductive layer 110-1 is formed on the second ILD layer 104. The first conductive layer 110-1 forms a first electrode (e.g., a bottom electrode) of the MIM capacitor device 130. The first conductive layer 110-1 is formed by depositing a layer of metallic material on the second ILD layer 104 and patterning the layer of metallic material to form the first capacitor electrode. In one embodiment, the first conductive layer 110-1 is formed of titanium nitride (TiN). In other embodiments, the first conductive layer 110-1 is formed of other types of metallic materials (e.g., Al, AlCu alloys, Ti, TaN, and/or Ta), depending on the given application. In at least some embodiments, the first ILD layer 101 and/or the second ILD layer 104 can comprise multiple layers and/or multiple dielectric materials.

A first dielectric layer 112-1 (e.g., a high-k dielectric layer) is deposited on a top surface and on exposed side surfaces of the first conductive layer 110-1 and on the second ILD layer 104. The process for forming the first dielectric layer 112-1 can include patterning of the first conductive layer 110-1 to form open regions and then depositing the first dielectric layer 112-1. The open regions in FIG. 3 can include, for example, the portion of first dielectric layer 112-1 that is formed on the second ILD layer 104. The patterning can be formed, for example, using an organic planarization layer (OPL) and lithography, and then wet etching or dry etching with, for example, chlorine, etc. The first dielectric layer 112-1 can be deposited using one or more processes such as ALD, for example, which allows for high conformality.

In some embodiments, the first dielectric layer 112-1 is formed of a metal oxide such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, lead zinc niobate, or any high-k dielectric material that is suitable for use as a dielectric layer for a MIM capacitor. The thickness of the first dielectric layer 112-1 will depend on the desired amount of capacitance of the MIM capacitor structure, wherein the capacitance is directly proportional to the dielectric constant of the first dielectric layer 112-1 and inversely proportional to the thickness of the first dielectric layer 112-1.

A second conductive layer 110-2 forms a second electrode of the MIM capacitor device 130. In one embodiment, the second conductive layer 110-2 is formed of the same metallic material as the first conductive layer 110-1. For instance, the second conductive layer 110-2 can be formed of Ti or Al, or other metallic materials which are suitable for fabricating MIM capacitor electrodes. In another embodiment, the second conductive layer 110-2 can be formed of a metallic material different from that of the first conductive layer 110-1. As shown in FIG. 3, the second conductive layer 110-2 is deposited on exposed top and side surfaces of the first dielectric layer 112-1. Due to the conformal nature of its deposition, the second conductive layer 110-2 includes areas of lower height (e.g., relative to a top surface of the second ILD layer 104) than other areas of the second conductive layer 110-2. The areas of lower height of the second conductive layer 110-2 are consistent with the areas of lower height of the first dielectric layer 112-1.

A second dielectric layer 112-2 is deposited on top surfaces and exposed side surfaces of the second conductive layer 110-2, as well as on exposed top surfaces and side surfaces of the first dielectric layer 112-1. The process for forming the second dielectric layer 112-2 can include patterning of the second conductive layer 110-2 to form one or more open regions (e.g., the region in FIG. 3 corresponding to where the first dielectric layer 112-1 is connected to the second dielectric layer 112-2). The patterning can be performed using, for example, an OPL and lithography, followed by wet etching or dry etching with, for example, chlorine (Cl⁻) to form the open regions. In one embodiment, the second dielectric layer 112-2 is formed of the same or similar material and thickness as the first dielectric layer 112-1. Similar to the first dielectric layer 112-1, capacitance is directly proportional to the dielectric constant of the second dielectric layer 112-2 and inversely proportional to the thickness of the second dielectric layer 112-2. In some embodiments, the first dielectric layer 112-1 and/or the second dielectric layer 112-2 can comprise multiple layers and/or multiple dielectric materials.

A third conductive layer 110-3 forms a third electrode of the MIM capacitor device 130 (e.g., a top electrode of a three-electrode MIM capacitor). In one embodiment, the third conductive layer 110-3 is formed using similar techniques and materials as the first and second conductive layers 110-1 and 110-2. For example, in some embodiments, the third conductive layer 110-3 can be formed of the same metallic material as the first and/or second conductive layers 110-1 and 110-2. In other embodiments, the third conductive layer 110-3 can be formed of a metallic material different from that of the first conductive layer 110-1 and/or the second conductive layer 110-2. As can be seen, the third conductive layer 110-3 is deposited on exposed top and side surfaces of the second dielectric layer 112-2. Due to the conformal nature of its deposition, the third conductive layer 110-3 includes areas of lower height (e.g., relative to a top surface of the second ILD layer 104) than other areas of the third conductive layer 110-3. The areas of lower height of the third conductive layer 110-3 are consistent with the areas of lower height of the second dielectric layer 112-2.

In FIG. 3, portions of the first dielectric layer 112-1 have been etched and removed so that the left side surface of the first dielectric layer 112-1 is aligned with a side surface of the second conductive layer 110-2, and that the right side surface of the first dielectric layer 112-1 is aligned with side surfaces of the first conductive layer 110-1 and the third conductive layer 110-3. In other embodiments, the left side surface of the first dielectric layer 112-1 can extend beyond the side surface of the second conductive layer 110-2 and/or the right side surface can extend beyond the side surfaces of the first conductive layer 110-1 and the third conductive layer 110-3. In such embodiments, one or more of the side surfaces of the second dielectric layer 112-2 can also extend beyond the side surfaces of the first conductive layer 110-1, the second conductive layer 110-2, and/or the third conductive layer 110-3.

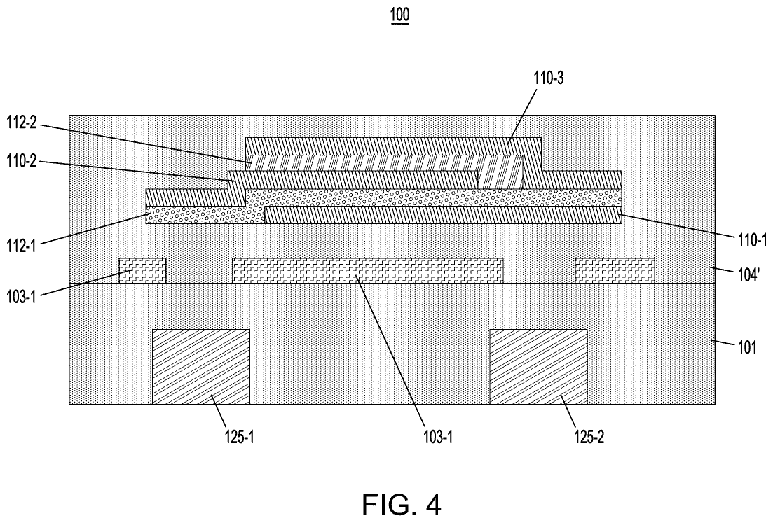

FIG. 4 is a schematic cross-sectional view of the capacitor structure 100 following deposition of dielectric material to extend the second ILD layer 104 to a level above the MIM capacitor device 130, thereby forming second ILD layer 104′. In some embodiments, the dielectric material is a same or similar material to that of the first ILD layer 101 and/or the second ILD layer 104. The dielectric material can be deposited to cover the MIM capacitor device 130. In some embodiments, the surface of the second ILD layer 104′ is planarized (e.g., using a chemical mechanical polishing (CMP) process) down to a target thickness.

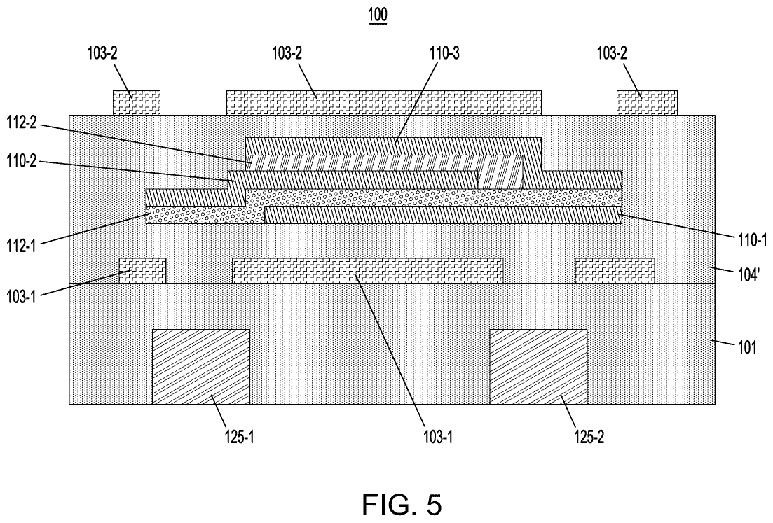

FIG. 5 is a schematic cross-sectional view of the capacitor structure 100 following formation of a second protection layer 103-2. The second protection layer 103-2 can be formed using similar materials and techniques as the first protection layer 103-1. For example, the second protection layer 103-2 can be formed on the second ILD layer 104′ above the MIM capacitor device 130. The process for forming the second protection layer 103-2 can include depositing a reflective material comprising one or more reflective metals (e.g., aluminum, platinum, chromium, or tungsten), and then patterning the reflective material with, for example, lithography and etching to form the second protection layer 103-2. In some embodiments, the second protection layer 103-2 can be formed of the same material as the first protection layer 103-1. In other embodiments, the second protection layer 103-2 is formed of a different material than the first protection layer 103-1. In some embodiments, the second protection layer 103-2 is formed with a thickness suitable for blocking incoming IR laser irradiation energy. In one embodiment, the thickness of the second protection layer 103-2 is approximately 100 nm or greater. In some embodiments, the second protection layer 103-2 is formed with any other suitable process (e.g., a damascene process).

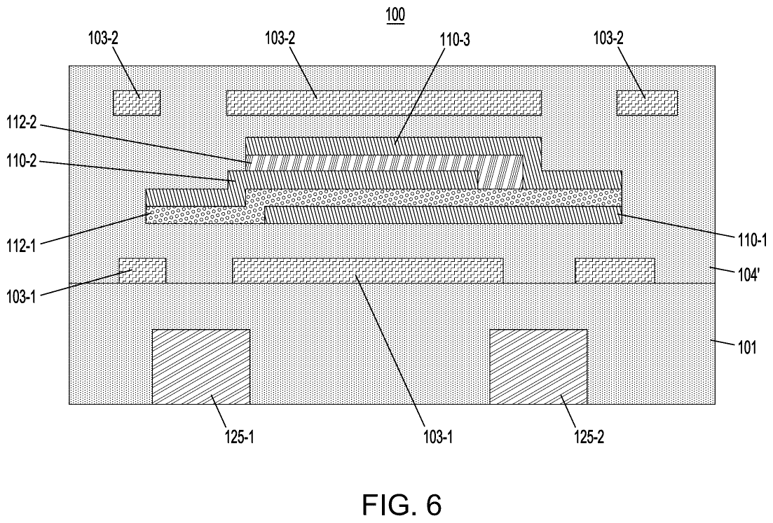

FIG. 6 is a schematic cross-sectional view of the capacitor structure 100 following deposition of additional dielectric material to extend the second ILD layer 104′ so that it surrounds and extends above the second protection layer 103-2. The additional dielectric material is deposited using known deposition techniques, such as ALD, CVD, PECVD, PVD, or spin-on deposition.

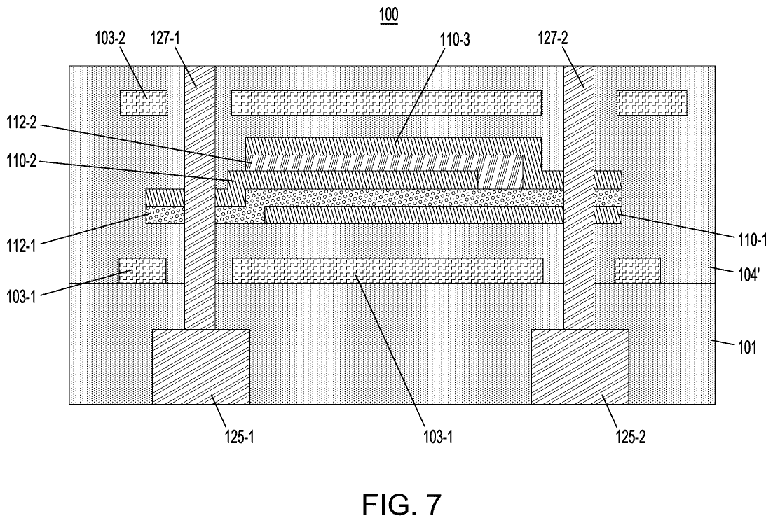

FIG. 7 is a schematic cross-sectional view of the capacitor structure 100 following formation of vias 127-1 and 127-2 (collectively “vias 127”), according to an embodiment. Via 127-1 is formed by forming a trench that extends through the second ILD layer 104′, the first dielectric layer 112-1, the second conductive layer 110-2, and into the first ILD layer 101 to expose a top surface of the conductive line 125-1. A trench can also be formed for via 127-2 that extends through the second ILD layer 104′, the first conductive layer 110-1, the second dielectric layer 112-1, and the third conductive layer 110-3, and into the first ILD layer 101 to expose a top surface of the conductive line 125-2. In some embodiments, the trenches are formed by depositing an etch mask on the second ILD layer 104′ with openings exposing portions of the second ILD layer 104′ where the trenches are to be formed, and then performing one or more etching processes to form the trenches. The trenches are filled with conductive material to form the vias 127. In an illustrative embodiment, one or more layers of liner material are deposited to line the side and bottom surfaces of the trenches with a liner (e.g., diffusion barrier layer and/or seed layer), and a layer of metallic material is deposited to fill the trenches. The top surface of the capacitor structure 100 is planarized to remove excess liner and metallic material of the deposited layers, resulting in the structure shown in FIG. 7. In one or more embodiments, the liner may be formed of one or more conformal layers of metallic material such as a titanium (Ti) and/or titanium nitride (TiN) liner, to line the bottom and side surfaces of the trenches. In one or more embodiments, the metallic fill material comprises, for example, copper, tungsten, cobalt, ruthenium, etc. The vias 127-1 and 127-2 extend down to and contact the respective conductive lines 125-1 and 125-2.

FIG. 8 is a schematic cross-sectional view of the capacitor structure shown following formation of a third ILD layer 105 and conductive lines 128-1 and 128-2 (collectively conductive lines 128), according to an embodiment. The third ILD layer 105 is formed using similar techniques and materials as the first ILD layer 101 and/or the second ILD layer 104. In one embodiment, the third ILD layer 105 comprises the same material as or a similar material to that of the first ILD layer 101 and/or the second ILD layer 104. The third ILD layer 105 is formed by a process which includes depositing a layer of dielectric material to cover the top surface of the second ILD layer 104′ and the top surfaces of vias 127, and planarizing the deposited layer of the dielectric material down to a target thickness (e.g., using a CMP process).

The conductive lines 128 are formed by patterning trenches in the third ILD layer 105, lining the trenches with a liner layer (e.g., diffusion barrier and/or seed layer), and filling the trenches with metallic material such as copper or other suitable metallic materials. In some embodiments, the conductive lines 128 are formed as part of an upper metallization layer Mₙ₊₁ of the capacitor structure 100, and the conductive lines 125 are formed as part of a lower metallization layer Mₙ, as shown in FIG. 6.

In FIGS. 7 and 8, it is assumed that the vias 127 and the conductive lines 128 are formed separately (e.g., using a single damascene process). However, it is to be appreciated that in other embodiments, the vias 127 and the conductive lines 128 are etched and formed together using a dual damascene process, for example.

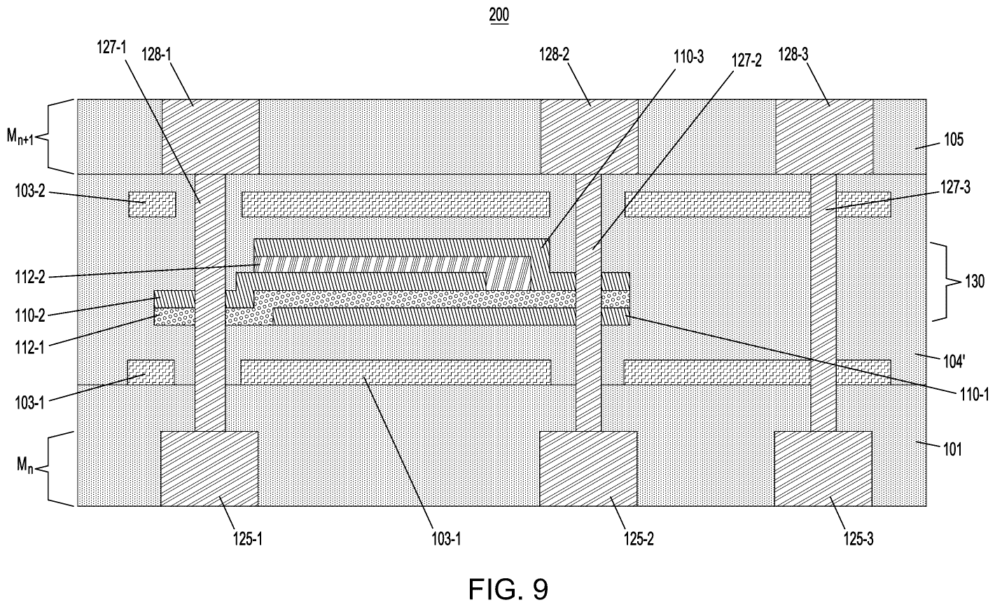

FIG. 9 is a schematic cross-sectional view of a capacitor structure 200, according to an embodiment. The capacitor structure 200 is similar to the capacitor structure 100 shown in FIG. 8, except the first protection layer 103-1 and the second protection layer 103-2 are further extended to the right of the MIM capacitor device 130. The capacitor structure 200 also includes additional conductive lines 125-3 and 128-3 and an additional via 127-3. The conductive lines 125-3 and 128-3 are formed using similar processes and materials as conductive lines 125-1 and 128-1, for example. In some embodiments, the additional via 127-3 connects the first protection layer 103-1 and the second protection layer 103-2 to ground or another voltage to at least partially mitigate detrimental phenomena (e.g., floating charges, antenna effects, etc.) that can pose a risk to electrical noise or dielectric breakdown.

It is to be appreciated that in other embodiments, one or more of the first protection layer 103-1 and the second protection layer 103-2 can be extended in either direction of the MIM capacitor device 130, and the additional via 127-3 can connect to one of the first protection layer 103-1 and the second protection layer 103-2, and a fourth via can optionally connect to the other one of the one of the first protection layer 103-1 and the second protection layer 103-2.

In other embodiments, at least one of the vias 127-1 and 127-2 of the capacitor structure 100 and/or 200 can also connect to at least one of the first protection layer 103-1 and the second protection layer 103-2.

Embodiments described herein provide a capacitor structure that incorporates protection layers both above and below MIM capacitor device to safeguard its electrodes from damage caused by laser energy during semiconductor manufacturing processes. Such a structure can advantageously prevent physical damage to the electrode components when performing laser-assisted processes, thereby enhancing overall reliability and performance of integrated circuits that incorporate these capacitors. Embedding protection layers within BEOL layers ensures robustness against detrimental effects of infrared laser irradiation without compromising the compact form factor or fabrication efficiency. Additionally, some embodiments can at least partially mitigate detrimental effects that can potentially result from the protection layers.

In one embodiment, a capacitor structure includes at least one metal-insulator-metal capacitor device and at least one protection layer vertically overlapped with at least a portion of the at least one metal-insulator-metal capacitor device. The capacitor structure includes a first metallization layer and a second metallization layer, where the at least one metal-insulator-metal capacitor device is positioned between the first and the second metallization layers.

In embodiments, the at least one protection layer may be positioned below the at least one metal-insulator-metal capacitor device.

In embodiments, a combined area of the at least one protection layer and the first metallization layer may cover an entire area below a bottom surface of the at least one metal-insulator-metal capacitor device.

In embodiments, the capacitor structure may further include at least one other protection layer vertically overlapped with at least a portion of the at least one metal-insulator-metal capacitor device, where the at least one other protection layer is positioned above the at least one metal-insulator-metal capacitor device.

In embodiments, a combined area of the at least one other protection layer and the second metallization layer may cover an entire area above a top surface of the at least one metal-insulator-metal capacitor device.

In embodiments, the at least one metal-insulator-metal capacitor device may include two or more electrodes, where each of the two or more electrodes is separated by a corresponding insulator layer.

In embodiments, the capacitor structure may further include a first via that electrically connects the first metallization layer to a first one of the two or more electrodes, and a second via that electrically connects the second metallization layer to a second one of the two or more electrodes.

In embodiments, at least a portion of the first via may be adjacent to the at least one protection layer, and at least a portion of the second via may be adjacent to the at least one other protection layer.

In embodiments, the capacitor structure may further include a third via connected to a portion of at least one of the first metallization layer and the second metallization layer that does not vertically overlap with the at least one metal-insulator-metal capacitor device.

In embodiments, the at least one protection layer may include a reflective metal material.

In embodiments, the reflective metal material may include at least one of aluminum, platinum, chromium, and tungsten.

In embodiments, a thickness of the at least one protection layer may be sufficient to block incoming infrared laser irradiation energy.

In embodiments, the thickness of the at least one protection layer may be at least 100 nm.

In another embodiment, a capacitor structure includes a metal-insulator-metal capacitor device and at least one protection layer vertically overlapped with at least a portion of the metal-insulator-metal capacitor device. The capacitor structure also includes at least one metallization layer, where a combined area of the at least one protection layer and the at least one metallization layer covers an entire area of a first surface of the metal-insulator-metal capacitor device.

In embodiments, the at least one protection layer may be embedded in one or more back-end-of-line layers of the capacitor structure.

In embodiments, the capacitor structure may include at least one other protection layer vertically overlapped with at least a portion of the metal-insulator-metal capacitor device and at least one other metallization layer, where a combined area of the at least one other protection layer and the at least one other metallization layer covers an entire area of a second surface of the metal-insulator-metal capacitor device.

In embodiments, the first surface may correspond to a bottom surface of the metal-insulator-metal capacitor device, and the second surface may correspond to a top surface of the metal-insulator-metal capacitor device.

In embodiments, the capacitor structure may include a first via that electrically connects the at least one metallization layer to a first electrode of the metal-insulator-metal capacitor device, a second via that electrically connects the at least one other metallization layer to a second electrode of the metal-insulator-metal capacitor device, and a third via connected to a portion of one or more of the at least one metallization layer and the at least one other metallization layer that does not vertically overlap with the metal-insulator-metal capacitor device.

In embodiments, the at least one protection layer and/or the at least one other protection layer may include multiple protection layers.

In embodiments, the at least one protection layer and/or the at least one other protection layer may include a reflective metal material comprising at least one of aluminum, platinum, chromium, and tungsten.

In another embodiment, a method includes depositing a first protection layer above a first metallization layer of a capacitor structure and forming a metal-insulator-metal capacitor device above the first protection layer. The method also includes depositing a second protection layer above the metal-insulator-metal capacitor device, and forming at least two vias, where a first one of the at least two vias electrically connects the first metallization layer to a first electrode of the metal-insulator-metal capacitor device and a second one of the at least two vias electrically connects a second metallization layer of the capacitor structure to a second electrode of the metal-insulator-metal capacitor device.

Capacitor structures and devices and methods for forming the same in accordance with the above-described techniques can be employed in various applications, hardware, and/or electronic systems. Suitable hardware and systems for implementing embodiments of the present disclosure may include, but are not limited to, personal computers, communication networks, electronic commerce systems, portable communications devices (for example, cell and smart phones), solid-state media storage devices, functional circuitry, etc. Systems and hardware incorporating the semiconductor devices are contemplated embodiments of the present disclosure. Given the teachings provided herein, one of ordinary skill in the art will be able to contemplate other implementations and applications of embodiments of the present disclosure.

In some embodiments, the above-described techniques are used in connection with semiconductor devices that may require or otherwise utilize, for example, Complementary Metal-Oxide-Semiconductors (CMOSs), Metal-Oxide-Semiconductor Field-Effect Transistors (MOSFETs), and/or Fin Field-Effect Transistors (FinFETs). By way of non-limiting example, the semiconductor devices can include, but are not limited to, CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the various layers, structures, and regions shown in the figures are schematic illustrations that are not drawn to scale. In addition, for ease of explanation, one or more layers, structures, and regions of a type commonly used to form capacitor devices or structures may not be explicitly shown in a given figure. This does not imply that any layers, structures, and regions not explicitly shown are omitted from the actual capacitor structures. Furthermore, it is to be understood that the embodiments discussed herein are not limited to the particular materials, features, and processing steps shown and described herein. In particular, with respect to capacitor processing steps, it is to be emphasized that the descriptions provided herein are not intended to encompass all of the processing steps that may be required to form a functional semiconductor integrated circuit device. Rather, certain processing steps that are commonly used in forming semiconductor and/or capacitor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures is not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments described herein have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A capacitor structure comprising:
at least one metal-insulator-metal capacitor device;
at least one protection layer vertically overlapped with at least a portion of the at least one metal-insulator-metal capacitor device; and
a first metallization layer and a second metallization layer, wherein the at least one metal-insulator-metal capacitor device is positioned between the first and the second metallization layers.

2. The capacitor structure of claim 1, wherein the at least one protection layer is positioned below the at least one metal-insulator-metal capacitor device.

3. The capacitor structure of claim 2, wherein a combined area of the at least one protection layer and the first metallization layer covers an entire area below a bottom surface of the at least one metal-insulator-metal capacitor device.

4. The capacitor structure of claim 2, further comprising:
at least one other protection layer vertically overlapped with at least a portion of the at least one metal-insulator-metal capacitor device, wherein the at least one other protection layer is positioned above the at least one metal-insulator-metal capacitor device.

5. The capacitor structure of claim 4, wherein a combined area of the at least one other protection layer and the second metallization layer covers an entire area above a top surface of the at least one metal-insulator-metal capacitor device.

6. The capacitor structure of claim 1, wherein the at least one metal-insulator-metal capacitor device comprises two or more electrodes, wherein each of the two or more electrodes is separated by a corresponding insulator layer.

7. The capacitor structure of claim 6, further comprising:
a first via that electrically connects the first metallization layer to a first one of the two or more electrodes; and
a second via that electrically connects the second metallization layer to a second one of the two or more electrodes.

8. The capacitor structure of claim 7, wherein at least a portion of the first via is adjacent to the at least one protection layer.

9. The capacitor structure of claim 7, further comprising:
a third via connected to a portion of at least one of the first metallization layer and the second metallization layer that does not vertically overlap with the at least one metal-insulator-metal capacitor device.

10. The capacitor structure of claim 1, wherein the at least one protection layer comprises a reflective metal material.

11. The capacitor structure of claim 10, wherein the reflective metal material comprises at least one of aluminum, platinum, chromium, and tungsten.

12. The capacitor structure of claim 1, wherein a thickness of the at least one protection layer is sufficient to block incoming infrared laser irradiation energy.

13. The capacitor structure of claim 12, wherein the thickness of the at least one protection layer is at least 100 nm.

14. A capacitor structure comprising:
a metal-insulator-metal capacitor device;
at least one protection layer vertically overlapped with at least a portion of the metal-insulator-metal capacitor device; and
at least one metallization layer;
wherein a combined area of the at least one protection layer and the at least one metallization layer covers an entire area of a first surface of the metal-insulator-metal capacitor device.

15. The capacitor structure of claim 14, wherein the at least one protection layer is embedded in one or more back-end-of-line layers of the capacitor structure.

16. The capacitor structure of claim 14, further comprising:
at least one other protection layer vertically overlapped with at least a portion of the metal-insulator-metal capacitor device; and
at least one other metallization layer, wherein a combined area of the at least one other protection layer and the at least one other metallization layer covers an entire area of a second surface of the metal-insulator-metal capacitor device.

17. The capacitor structure of claim 16, wherein the first surface corresponds to a bottom surface of the metal-insulator-metal capacitor device, and the second surface corresponds to a top surface of the metal-insulator-metal capacitor device.

18. The capacitor structure of claim 16, further comprising:
a first via that electrically connects the at least one metallization layer to a first electrode of the metal-insulator-metal capacitor device;
a second via that electrically connects the at least one other metallization layer to a second electrode of the metal-insulator-metal capacitor device; and
a third via connected to a portion of one or more of the at least one metallization layer and the at least one other metallization layer that does not vertically overlap with the metal-insulator-metal capacitor device.

19. The capacitor structure of claim 14, wherein the at least one protection layer comprises at least one of:
multiple protection layers; and
a reflective metal material comprising at least one of aluminum, platinum, chromium, and tungsten.

20. A method, comprising:
depositing a first protection layer above a first metallization layer of a capacitor structure;
forming a metal-insulator-metal capacitor device above the first protection layer;
depositing a second protection layer above the metal-insulator-metal capacitor device; and
forming at least two vias, wherein a first one of the at least two vias electrically connects the first metallization layer to a first electrode of the metal-insulator-metal capacitor device and a second of the at least two vias electrically connects a second metallization layer of the capacitor structure to a second electrode of the metal-insulator-metal capacitor device.
